(19) United States
(12) Patent Application Publication
(10) Pub. No.: US 2024/0276653 A1
(43) Pub. Date: Aug. 15, 2024

(54) WIRING BOARD AND WIRING BOARD MANUFACTURING METHOD

(71) Applicant: SHINKO ELECTRIC INDUSTRIES CO., LTD., Nagano-shi (JP)

(72) Inventor: Naohiro Mashino, Nagano (JP)

(21) Appl. No.: 18/427,147

(22) Filed: Jan. 30, 2024

(30) Foreign Application Priority Data
Feb. 9, 2023 (JP) 2023-018065

(51) Int. Cl. H05K 3/46; H05K 3/14

(52) U.S. Cl. CPC H05K 3/467; H05K 3/146; H05K 3/4605; H05K 2203/063; H05K 2203/1338

(57) ABSTRACT

A wiring board includes a wiring layer, an insulating layer, an oxide thin film, a seed layer, and a conductive layer. The insulating layer is laminated on the wiring layer and includes an opening portion that penetrates until the wiring layer. The oxide thin film is formed on a surface of the insulating layer including an inner wall surface of the opening portion. The seed layer is made of metal and that is laminated on the oxide thin film at a position of the opening portion. The conductive layer is formed on the seed layer. The oxide thin film is a thin film that has a thickness of 1 to 100 angstroms and covers a surface of the insulating layer including the inner wall surface of the opening portion and a surface of the wiring layer exposed from a bottom portion of the opening portion.

### CROSS-REFERENCE TO RELATED APPLICATION

This application is based upon and claims the benefit of priority of the prior Japanese Patent Application No. 2023-018065, filed on Feb. 9, 2023, the entire contents of which are incorporated herein by reference.

### FIELD

The embodiment discussed herein is related to a wiring board and a wiring board manufacturing method.

### BACKGROUND

In general, a wiring board that includes micro wiring is manufactured by forming a seed layer that serves as a cathode on a surface of an insulating base material, such as polyimide, and forming a conductive layer that is made of metal, such as copper, by, for example, electrolytic plating on the seed layer. Further, in some cases, an adhesive layer using metal, such as titanium, may be formed between the seed layer and the base material in order to improve adhesiveness between the seed layer and the base material.

The adhesive layer is formed by using, for example, Atomic Layer Deposition (ALD). As the adhesive layer, for example, a transition metal oxide, such as titanium or hafnium, may be used, and in this case, an insulating adhesive layer is formed.

Patent Literature 1: Japanese Laid-open Patent Publication No. 2006-120870

Patent Literature 2: Japanese Patent No. 6432280

Meanwhile, in some cases, a wiring board includes a multilayer wiring structure that is formed by, for example, a semi-additive method. Specifically, a wiring layer is formed by performing electroless plating or electrolytic plating on an insulating base material or an insulating layer, such as polyimide, and an insulating layer that covers the wiring layer is further formed. In this manner, by repeatedly laminating the insulating layer and the wiring layer, a wiring board that has a multilayer wiring structure is formed.

In the wiring board that has the multilayer wiring structure, a via that penetrates through the insulating layer is arranged if needed, and wiring patterns on different wiring layers are electrically connected to each other. The via and the wiring layers around the via are formed by forming an opening portion in the insulating layer, forming a seed layer by electroless plating on a surface of the insulating layer including an inner wall surface of the opening portion, and performing, for example, electrolytic plating on the seed layer.

Further, even in the wiring board that has the multilayer wiring structure, in some cases, an insulating adhesive layer may be formed between the seed layer and the insulating layer. In this case, the adhesive layer is formed on the surface of the insulating layer including the inner wall surface of the opening portion of the insulating layer, the adhesive layer at a bottom portion of the opening portion is removed, and the seed layer is formed on the wiring layer that is exposed from the bottom portion of the opening portion and the remaining adhesive layer, so that the seed layer and the wiring layer is electrically conducted to each other. The adhesive layer at the bottom portion of the opening portion of the insulating layer is removed by, for example, dry etching, such as argon reverse sputtering.

However, in the wiring board in which the seed layer and the wiring layer are electrically connected by removing the adhesive layer by dry etching, there is a problem in that adhesiveness in the adhesive layer may be degraded although it is possible to establish electrical conductivity between the seed layer and the wiring layer. Specifically, when the adhesive layer at the bottom portion of the opening portion of the insulating layer is removed by dry etching, surface roughness of the remaining adhesive layer may be increased, so that the adhesiveness between the seed layer and the insulating layer via the adhesive layer may be degraded. Therefore, there is a need for a technology for obtaining an adhesive layer that has both of adhesiveness and electrical conductivity without removing the adhesive layer by dry etching.

### SUMMARY

According to an aspect of an embodiment, a wiring board includes a wiring layer; an insulating layer that is laminated on the wiring layer and that includes an opening portion that penetrates until the wiring layer; an insulating oxide thin film that is formed by depositing one of a metal oxide and a metalloid oxide on a surface of the insulating layer including an inner wall surface of the opening portion; a seed layer that is made of metal and that is laminated on the oxide thin film at a position of the opening portion; and a conductive layer that is formed on the seed layer, wherein the oxide thin film is a thin film that has a thickness of 1 to 100 angstroms and covers a surface of the insulating layer including the inner wall surface of the opening portion and a surface of the wiring layer exposed from a bottom portion of the opening portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring board according to one embodiment;

FIG. 2 is a diagram illustrating an example of an experimental result obtained by examining a relationship between a thickness of an oxide thin film and water vapor permeability of the oxide thin film;

FIG. 3 is an enlarged view of a portion A in FIG. 1;

FIG. 4 is a flowchart illustrating a method of manufacturing the wiring board according to one embodiment;

FIG. 5 is a diagram illustrating a specific example of a support substrate formation process;

FIG. 6 is a diagram illustrating a specific example of an insulating layer formation process;

FIG. 7 is a diagram illustrating a specific example of an opening portion formation process;

FIG. 8 is a diagram illustrating a specific example of an oxide thin film formation process;

FIG. 9 is a diagram illustrating a specific example of a seed layer formation process;

FIG. 10 is a diagram illustrating a specific example of a resist layer formation process;

FIG. 11 is a diagram illustrating a specific example of an electrolytic plating process;

FIG. 12 is a diagram illustrating a specific example of a resist layer removal process; and

FIG. 13 is a diagram illustrating a specific example of an etching process.

### DESCRIPTION OF EMBODIMENT

Embodiments of a wiring board and a wiring board manufacturing method disclosed in the present application will be described in detail below based on the drawings. The disclosed technology is not limited by the embodiments below.

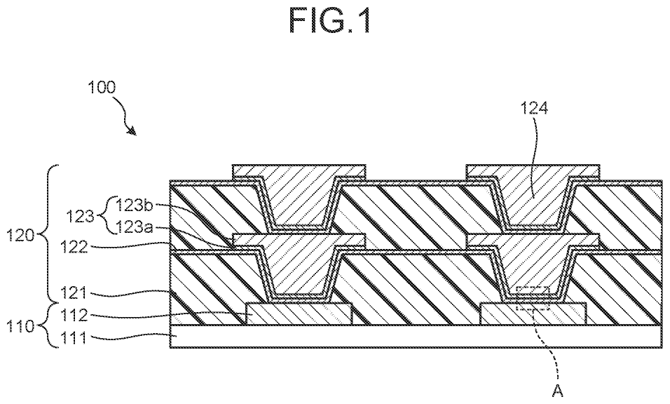

FIG. 1 is a diagram illustrating a configuration of a wiring board 100 according to one embodiment. In FIG. 1, a cross section of the wiring board 100 is schematically illustrated.

The wiring board 100 has a layer structure and includes a support substrate 110 and a multilayer wiring structure 120. In the following, as illustrated in FIG. 1, it is assumed that a base material 111 of the support substrate 110 serves as a lowermost layer and a vertical direction is defined in accordance with the lowermost layer; however, the wiring board 100 may be used upside down or may be used in an arbitrary posture, for example.

The support substrate 110 is formed by forming a wiring layer 112 by metal plating on an upper surface of the base material 111 that is a plate-like insulator. The wiring layer 112 may be connected to a different wiring layer (not illustrated) located below the base material 111 via via wiring or the like (not illustrated) that penetrates through the base material 111.

The multilayer wiring structure 120 is formed by laminating layers each including an insulating layer 121, an oxide thin film 122, and a wiring layer 123.

The insulating layer 121 is formed by using non-photosensitive and thermosetting insulating resin that consists primarily of, for example, epoxy resin, polyimide resin, fluorine resin, or silicone resin. The insulating layer 121 may be inorganic material filler or glass fiber that is impregnated with epoxy resin, paper that is impregnated with phenolic resin, Teflon (registered trademark), liquid crystal polymer, silicon oxycarbide (SiOC), a ceramic inorganic material, or the like.

The oxide thin film 122 is an insulating thin film that is formed on a surface of the insulating layer 121, and is a layer that increases adhesiveness of the wiring layer 123 (a seed layer 123a to be described later) with respect to the insulating layer 121. The oxide thin film 122 may be a thin film that is formed by a film deposition technology, such as plasma atomic layer deposition (ALD) or thermal ALD using a metal oxide or a metalloid oxide, and that has a thickness of, for example, 1 to 100 angstroms (0.1 to 10 nanometers (nm)). The oxide thin film 122 is a thin film that is deposited by, for example, ALD, and therefore, adhesive strength of the oxide thin film 122 adhering to the insulating layer 121 is increased and adhesiveness to, for example, a three-dimensional structure and a side wall, such as a through hole, is also increased. As a material of the oxide thin film 122, it is preferable to use, for example, a hafnium oxide (hafnia), a zirconium oxide (zirconia), a titanium oxide (titania), a niobium pentoxide, or the like.

The wiring layer 123 is a conductive layer that is formed on a surface of the oxide thin film 122. The wiring layer 123 is formed by using, for example, metal, such as copper or a copper alloy.

In the wiring board 100 illustrated in FIG. 1, two layers each including the insulating layer 121, the oxide thin film 122, and the wiring layer 123 are laminated in the multilayer wiring structure 120 on the support substrate 110, but the number of the laminated layers may be one or may be three or more. The wiring layers 112 and 123 that are adjacent to each other via the insulating layer 121 may be connected to each other via vias 124 that penetrate through the insulating layer 121 if needed. At positions at which the vias 124 are formed, opening portions (hereinafter, appropriately referred to as “via holes”) are formed in the insulating layer 121, and the wiring layer 112 or the wiring layer 123 serving as a lower layer is exposed from bottom portions of the via holes. The insulating layer 121 is formed by using non-photosensitive and thermosetting resin, and therefore, it is possible to form the opening portions for forming the vias 124 by laser processing.

Structures of the oxide thin film 122, the vias 124, and the surrounding wiring layer 123 will be described in detail below. As illustrated in FIG. 1, the oxide thin film 122 that is a thin film with a thickness of 1 to 100 angstroms is formed on a surface of the insulating layer 121 including the inner wall surfaces of the opening portions (that is, the via holes). At positions at which the vias 124 are formed, that is, at positions of the via holes, the wiring layer 123 is formed of the seed layer 123a that is formed on the oxide thin film 122 and an electrolytic plating layer 123b (one example of a conductive layer) that is formed on the seed layer 123a. The seed layer 123a is formed by, for example, metal sputtering using copper or the like, and the electrolytic plating layer 123b is formed by, for example, electrolytic plating using copper or the like. The vias 124 are formed by applying electrolytic plating onto the seed layer 123a in the opening portions, (that is, the via holes) of the insulating layer 121. The wiring layer 123 and the vias 124 as described above are formed by, for example, a semi-additive method.

Further, at the bottom portions of the opening portions of the insulating layer 121 in which the vias 124 are formed, the wiring layer 112 is exposed, the oxide thin film 122 is formed on the exposed surface of the wiring layer 112, and the seed layer 123a is formed on the oxide thin film 122. If the thickness of the oxide thin film 122 is relatively large, the seed layer 123a and the wiring layer 112 that are located so as to sandwich the insulating oxide thin film 122 are not electrically connected to each other. Therefore, to establish electrical connection between the seed layer 123a and the wiring layer 112, the oxide thin film 122 at the bottom portions of the opening portions of the insulating layer 121 is generally removed by, for example, dry etching, such as argon reverse sputtering.

In contrast, by setting the thickness of the oxide thin film 122 to 1 to 100 angstroms (0.1 to 10 nm), the oxide thin film 122 becomes a porous body that appropriately includes apertures (defects), so that electrical connection between the seed layer 123a and the wiring layer 112 is ensured via the apertures of the oxide thin film 122. As a result, the oxide thin film 122 need not be removed by dry etching, so that it is possible to ensure the oxide thin film 122 that serves as an adhesive layer that has both of adhesiveness and electrical conductivity.

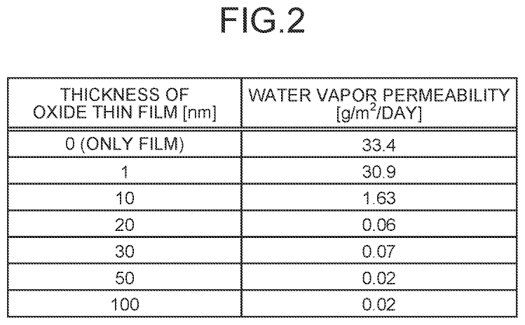

FIG. 2 is a diagram illustrating an example of an experimental result obtained by examining a relationship between the thickness of the oxide thin film 122 and water vapor permeability of the oxide thin film 122. The water vapor permeability indicates an amount of water vapor that permeates through a test piece of 1 m² in 24 hours (one day). The inventors of the present application found that, as a result of intensive research, the water vapor permeability of the oxide thin film 122 and electrical conductivity between conductors (for example, the seed layer 123a and the wiring layer 112) that sandwich the oxide thin film 122 are correlated with each other. Therefore, it is possible to use the water vapor permeability of the oxide thin film 122 as an index that represents electrical conductivity of the conductors that sandwich the oxide thin film 122.

In the experiment FIG. 2, a test piece obtained by forming the oxide thin film 122 on a film made of polyimide was used. Further, in the experiment, a thickness of the oxide thin film formed on the film was set to seven different thicknesses such as 0 nm, 1 nm, 10 nm, 20 nm, 30 nm, 50 nm, and 100 nm, and water vapor permeability of each of test pieces was measured.

As illustrated in FIG. 2, the water vapor permeability decreased with an increase in the thickness of the oxide thin film. In particular, when the thickness of the oxide thin film was 20 nm (200 angstroms), the water vapor permeability decreased to about 1/30 as compared to a case in which the thickness of the oxide thin film was 10 nm (100 angstroms). From the results in FIG. 2, it is found that, when the thickness of the oxide thin film 122 is set to 1 to 100 angstroms (0.1 to 10 nm), apertures (defects) that allow permeation of water molecules are formed in the oxide thin film 122 and electrical conductivity between the conductors that sandwich the oxide thin film 122 is ensured. Therefore, it is possible to conclude that, by setting the thickness of the oxide thin film 122 to 1 to 100 angstroms (0.1 to 10 nm), the oxide thin film 122 that serves as an adhesive layer that has both of adhesiveness and electrical conductivity can be obtained.

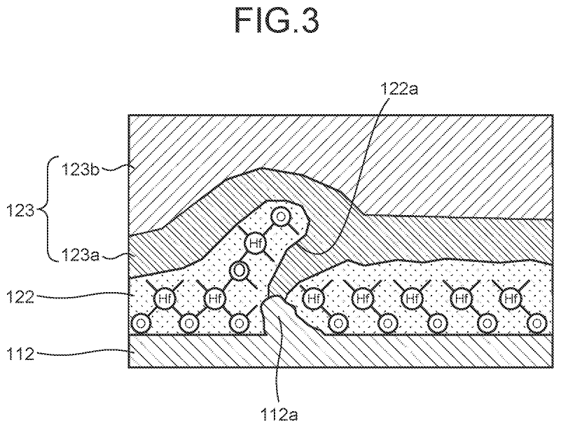

FIG. 3 is an enlarged view of a portion A in FIG. 1. In FIG. 3, a periphery of the surface of the wiring layer 112 exposed from the opening portion (that is, the via hole) of the insulating layer 121 is illustrated in an enlarged manner. Further, in FIG. 3, a hafnium oxide (hafnia) thin film that is deposited by using ALD is illustrated as an example of the oxide thin film 122.

As illustrated in FIG. 1 and FIG. 3, the oxide thin film 122 continuously covers the surface of the insulating layer 121 including the inner wall surface of the opening portion of the insulating layer 121 and the surface of the wiring layer 112 exposed from the bottom portion of the opening portion of the insulating layer 121. With this configuration, it is possible to increase adhesive strength of the oxide thin film 122 with respect to the insulating layer 121.

Further, as illustrated in FIG. 3, the oxide thin film 122 includes the one or more apertures 122a that reach the surface of the wiring layer 112 that is exposed from the opening portions of the insulating layer 121. For example, the oxide thin film 122 includes the apertures 122a at positions of defects of a crystal lattice that forms the oxide thin film 122. The apertures 122a penetrate through the oxide thin film 122 in a thickness direction, and has certain straightness to the extent that at least a water molecule can penetrate through the apertures. A part of the seed layer 123a is applied to the apertures of the oxide thin film 122 and comes into contact with the surface of the wiring layer 112. For example, a part of the seed layer 123a comes into contact with a protruding portion 112a that is formed by an oxide film on the surface of the wiring layer 112.

A part of the seed layer 123a comes into contact with the surface of the wiring layer 112 via the apertures 122a of the oxide thin film 122, so that it is possible to more stably ensure electrical connection between the seed layer 123a and the wiring layer 112.

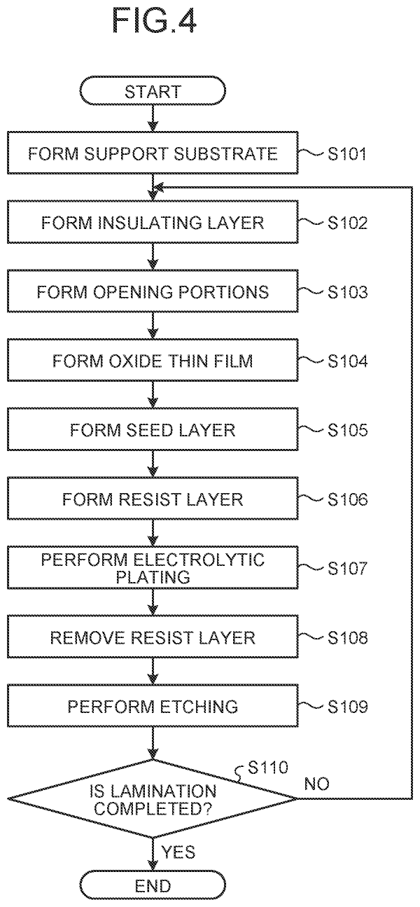

A method of manufacturing the wiring board 100 configured as described above will be described below with reference to FIG. 4 while giving specific examples. FIG. 4 is a flowchart illustrating the method of manufacturing the wiring board 100 according to one embodiment.

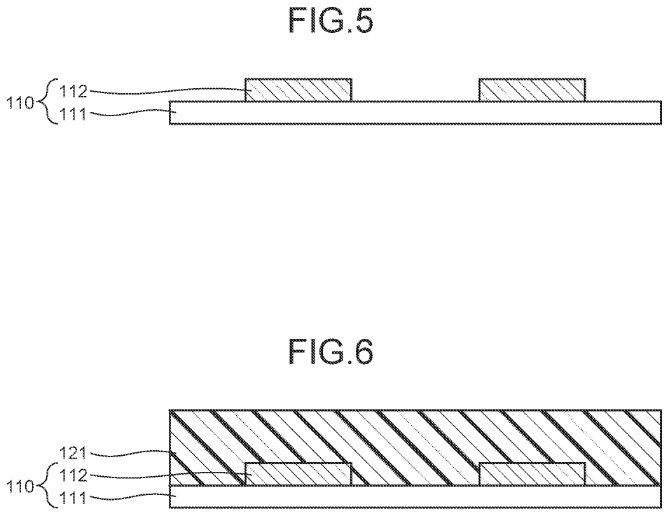

First, the support substrate 110 that serves as a support member of the wiring board 100 is formed (Step S101). Specifically, as illustrated in FIG. 5 for example, the wiring layer 112 that is made of, for example, metal, such as copper or a copper alloy, is formed on an upper surface of the base material 111 that is a plate-like insulator by, for example, a copper foil or copper plating. FIG. 5 is a diagram illustrating a specific example of a support substrate formation process. As the base material 111, for example, a silicon substrate, a glass substrate, or the like may be used. Further, as the base material 111, for example, a glass epoxy substrate or the like that is formed of a glass cloth impregnated with insulating resin, such as epoxy resin or polyimide resin, may be used other than the silicon substrate or the glass substrate. As a material of the wiring layer 112, for example, copper, a copper alloy, or the like may be used.

Further, the multilayer wiring structure 120 may be formed on the upper surface of the support substrate 110 by a build-up method. Specifically, as illustrated in FIG. 6 for example, the insulating layer 121 is first formed on the upper surface of the support substrate 110 (Step S102). FIG. 6 is a diagram illustrating a specific example of an insulating layer formation process. Specifically, the insulating layer 121 that is made of non-photosensitive and thermosetting insulating resin that consists primarily of, for example, epoxy resin, polyimide resin, fluorine resin, or silicone resin is formed on the wiring layer 112 of the support substrate 110.

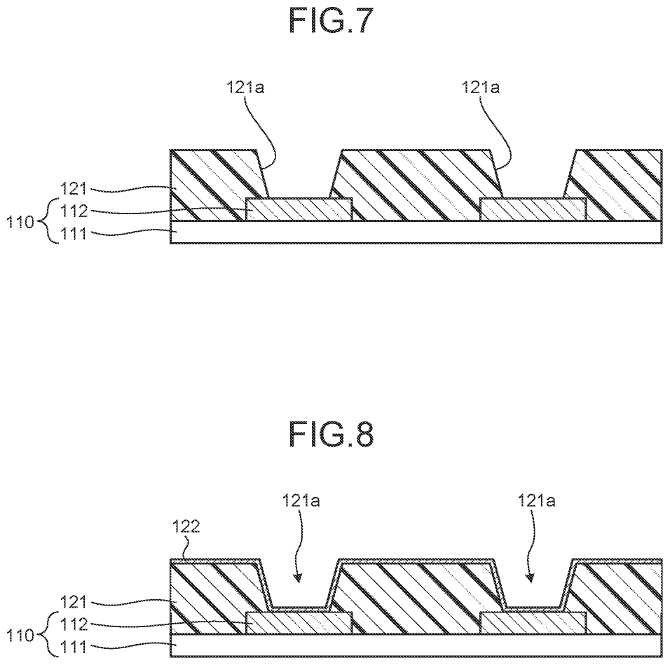

At positions at which the vias 124 are formed in the insulating layer 121, the opening portions (that is, the via holes) are formed (Step S103). Specifically, as illustrated in FIG. 7 for example, opening portions 121a that penetrate through the insulating layer 121 and that allow the wiring layer 112 to be exposed from the bottom portions are formed. FIG. 7 is a diagram illustrating a specific example of an opening portion formation process. The opening portions 121a may be formed by, for example, laser processing or the like using CO₂ laser. After the opening portions 121a are formed in the insulating layer 121, a desmearing process is performed to remove resin residue. In other words, the resin residue that remains in and around the opening portions 121a is removed by using, for example, a potassium permanganate solution.

Further, the oxide thin film 122 is formed on the surface of the insulating layer 121 in which the opening portions 121a are formed, by a film deposition technology, such as ALD (Step S104). Specifically, as illustrated in FIG. 8 for example, the oxide thin film 122 with a thickness of 1 to 100 angstroms (0.1 to 10 nm) is formed on the surface of the insulating layer 121 including the inner wall surfaces of the opening portions 121a. FIG. 8 is a diagram illustrating a specific example of an oxide thin film formation process. By setting the thickness of the oxide thin film 122 to 1 to 100 angstroms (0.1 to 10 nm), it is possible to form the one or more apertures 122a (see FIG. 3) in the oxide thin film 122 until the surface of the wiring layer 112 exposed from the opening portion 121a. The oxide thin film 122 is formed by using, for example, a metal oxide or a metalloid oxide, such as a hafnium oxide (hafnia), a zirconium oxide (zirconia), a titanium oxide (titania), or a niobium pentoxide, and by using a film deposition technology, such as ALD, that is able to form a thin film. If the ALD for forming the oxide thin film 122 is thermal ALD, temperature of 170 to 230° C. may be used as a temperature condition of the thermal ALD, for example. By forming the oxide thin film 122 by the ALD, it is possible to prevent reduction in the adhesive strength of the oxide thin film 122. The oxide thin film 122 is formed so as to cover the surface of the insulating layer 121 including the inner wall surfaces of the opening portions 121a and the surface of the wiring layer 112 exposed from the bottom portions of the opening portions 121a. The surface of the insulating layer 121 including the inner wall surfaces of the opening portions 121a and the surface of the wiring layer 112 exposed from the bottom portions of the opening portions 121a are continuously covered by the oxide thin film 122, so that it is possible to improve adhesiveness between the oxide thin film 122 and the insulating layer 121.

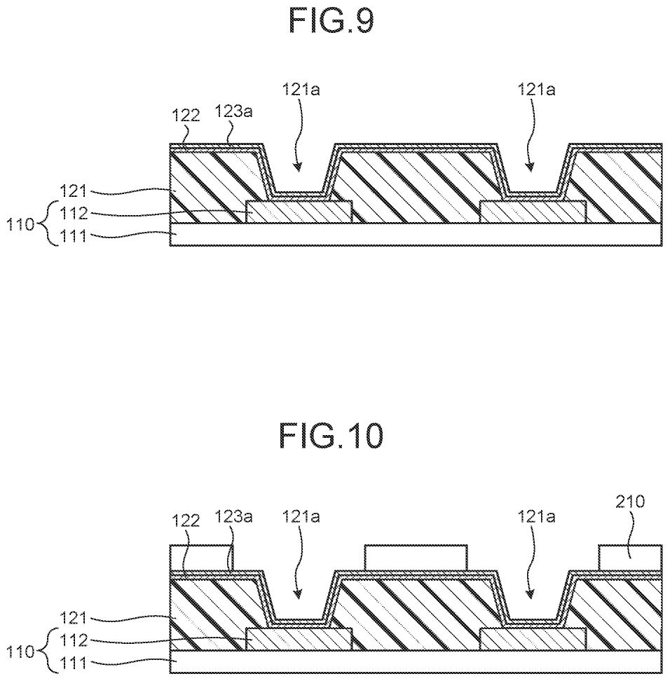

Furthermore, the seed layer 123a is formed on the surface of the oxide thin film 122 by sputtering (Step S105). Specifically, as illustrated in FIG. 9 for example, the seed layer 123a is formed on the surface of the oxide thin film 122 by, for example, metal sputtering using copper or the like. FIG. 9 is a diagram illustrating a specific example of a seed layer formation process. In this case, the oxide thin film 122 serving as an adhesive layer is formed as a lower layer of the seed layer 123a, so that preferable adhesiveness is ensured between the insulating layer 121 and the seed layer 123a. Moreover, the one or more apertures 122a (see FIG. 3) that reach the surface of the wiring layer 112 are formed in the oxide thin film 122, and a part of the seed layer 123a is applied to the apertures 122a and comes into contact with the surface of the wiring layer 112. With this configuration, it is possible to further stabilize electrical connection between the seed layer 123a and the wiring layer 112.

After the seed layer 123a is formed, a resist layer is formed on an upper surface of the seed layer 123a (Step S106). Specifically, as illustrated in FIG. 10 for example, a resist 210 including opening portions in regions in which wiring patterns are formed is formed. FIG. 10 is a diagram illustrating a specific example of a resist layer formation process.

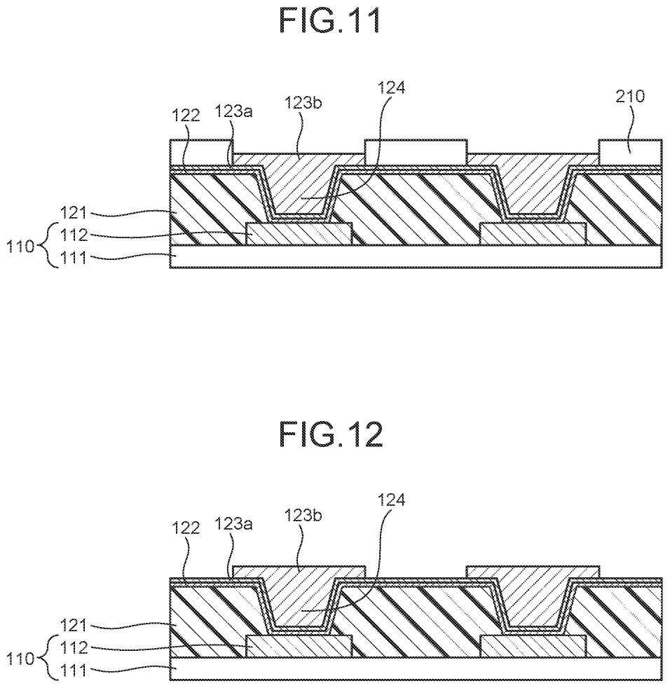

Furthermore, for example, copper electrolytic plating is performed on the upper surface of the seed layer 123a exposed from the opening portions of the resist 210 (Step S107). Specifically, as illustrated in FIG. 11 for example, copper is precipitated in the opening portions of the resist 210 and the electrolytic plating layer 123b is formed. At this time, copper electrolytic plating is applied to the opening portions 121a of the insulating layer 121, and the vias 124 that penetrate through the insulating layer 121 are formed. FIG. 11 is a diagram illustrating a specific example of an electrolytic plating process.

After the electrolytic plating layer 123b and the vias 124 are formed, the resist 210 is removed by, for example, an alkaline stripping solution (Step S108). Consequently, as illustrated in FIG. 12 for example, an intermediate structure in which the electrolytic plating layer 123b and the vias 124 are formed on the oxide thin film 122 and the seed layer 123a that are laminated on the surface of the insulating layer 121 is obtained. FIG. 12 is a diagram illustrating a specific example of a resist layer removal process.

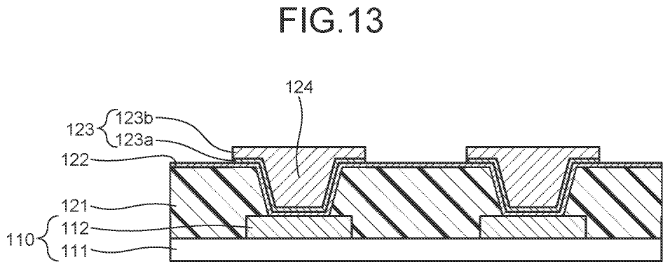

Moreover, the seed layer 123a that is not covered by the electrolytic plating layer 123b is removed by etching by using the electrolytic plating layer 123b as a mask (Step S109). Specifically, as illustrated in FIG. 13 for example, a part of the seed layer 123a, which is not covered by the electrolytic plating layer 123b, is removed by, for example, wet etching using an etching solution, such as sulfuric acid-hydrogen peroxide or persulfate. Consequently, the wiring layer 123 that has a desired wiring pattern is formed. FIG. 13 is a diagram illustrating a specific example of an etching process. At positions at which the vias 124 are formed, that is, at positions of the opening portions 121a of the insulating layer 121, the wiring layer 123 is formed of the seed layer 123a and the electrolytic plating layer 123b.

The formation of the insulating layer 121, the formation of the opening portion 121a, the formation of the oxide thin film 122, and the formation of the wiring layer 123 as described above are repeated a predetermined number of times, and a plurality of layers each including the insulating layer 121, the oxide thin film 122, and the wiring layer 123 are formed. Specifically if lamination of the layers each including the insulating layer 121, the oxide thin film 122, the wiring layer 123 is not completed (No at Step S110), the formation of the insulating layer 121, the formation of the opening portion 121a, the formation of the oxide thin film 122, and the formation of the wiring layer 123 as described above are repeated. In contrast, if lamination of the layers each including the insulating layer 121, the oxide thin film 122, and the wiring layer 123 is completed (Yes at Step S110), the multilayer wiring structure 120 is completed and the wiring board 100 as illustrated in FIG. 1 is obtained.

As described above, a wiring board according to one embodiment includes a wiring layer (for example, the wiring layer 112), an insulating layer (for example, the insulating layer 121), an oxide thin film (for example, the oxide thin film 122), a seed layer (for example, the seed layer 123a), and a conductive layer (for example, the electrolytic plating layer 123b). The insulating layer is laminated on the wiring layer and includes an opening portion (for example, the opening portion 121a) that penetrates until the wiring layer. The oxide thin film is an insulating oxide thin film that is formed by depositing one of a metal oxide and a metalloid oxide on a surface of the insulating layer including an inner wall surface of the opening portion. The seed layer is a seed layer that is made of metal and that is laminated on the oxide thin film at a position of the opening portion. The conductive layer is formed on the seed layer. The oxide thin film is a thin film that has a thickness of 1 to 100 angstroms. With this configuration, according to the wiring board of one embodiment, it is possible to obtain an adhesive layer (for example, the oxide thin film 122) that has both of adhesiveness and electrical conductivity.

Furthermore, the oxide thin film may cover a surface of the insulating layer including the inner wall surface of the opening portion and a surface of the wiring layer exposed from a bottom portion of the opening portion. With this configuration, according to the wiring board of one embodiment, it is possible to increase adhesive strength of the adhesive layer with respect to the insulating layer.

Moreover, the oxide thin film is a porous body that includes one or more apertures (for example, the apertures 122a) that reach the surface of the wiring layer exposed from the bottom portion of the opening portion, and a part of the seed layer may be applied to the one or more apertures in the oxide thin film and may come into contact with the surface of the wiring layer. With this configuration, according to the wiring board of one embodiment, it is possible to stably ensure electrical connection between the seed layer and the wiring layer via the adhesive layer.

Furthermore, the oxide thin film may be one of a hafnium oxide thin film, a zirconium oxide thin film, a titanium oxide thin film, and a niobium pentoxide thin film, which is deposited by using ALD. With this configuration, according to the wiring board of one embodiment, it is possible to prevent reduction in the adhesive strength of the adhesive layer.

According to one aspect of the wiring board disclosed in the present application, it is possible to obtain an adhesive layer that has both of adhesiveness and electrical conductivity.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

### Note

(1) A wiring board manufacturing method comprising: forming a wiring layer;
laminating an insulating layer on the wiring layer;

forming, on the insulating layer, an opening portion that penetrates until the wiring layer;
forming an insulating oxide film by one of a metal oxide and a metalloid oxide on a surface of the insulating layer including an inner wall surface of the opening portion;
forming a seed layer that is made of metal on the oxide thin film;
forming a conductive layer on the seed layer at a position of the opening portion; and
removing a part of the seed layer, the part not being covered by the conductive layer, wherein
the forming the oxide thin film includes forming the oxide thin film that has a thickness of 1 to 100 angstroms and that covers a surface of the insulating layer including the inner wall surface of the opening portion and a surface of the wiring layer exposed from a bottom portion of the opening portion.
(2) The wiring board manufacturing method according to the note (1), wherein the wiring layer are electrically connected to each other via an aperture that is arranged in the oxide thin film.

What is claimed is:

1. A wiring board comprising:
a wiring layer;
an insulating layer that is laminated on the wiring layer and that includes an opening portion that penetrates until the wiring layer;
an insulating oxide thin film that is formed by depositing one of a metal oxide and a metalloid oxide on a surface of the insulating layer including an inner wall surface of the opening portion;
a seed layer that is made of metal and that is laminated on the oxide thin film at a position of the opening portion; and
a conductive layer that is formed on the seed layer, wherein
the oxide thin film is a thin film that has a thickness of 1 to 100 angstroms and covers a surface of the insulating layer including the inner wall surface of the opening portion and a surface of the wiring layer exposed from a bottom portion of the opening portion.

2. The wiring board according to claim 1, wherein the wiring layer and the conductive layer are electrically connected to each other via an aperture that is provided in the oxide thin film.

3. The wiring board according to claim 1, wherein
the oxide thin film is a porous body that includes one or more apertures that reach the surface of the wiring layer exposed from the bottom portion of the opening portion, and
a part of the seed layer is filled in the one or more apertures in the oxide thin film and comes into contact with the surface of the wiring layer.

4. The wiring board according to claim 1, wherein the oxide thin film is one of a hafnium oxide thin film, a zirconium oxide thin film, a titanium oxide thin film, and a niobium pentoxide thin film.

5. The wiring board according to claim 4, wherein the oxide thin film is a thin film that is deposited by using atomic layer deposition (ALD).
